(19) United States
(12) Patent Application Publication
(10) Pub. No.: US 2007/0002549 A1
(43) Pub. Date: Jan. 4, 2007

(54) Electronic package connected to a substrate

(76) Inventors: Patricia A. Brusso, Chandler, AZ (US); Rhonda L. Higgins, Chandler, AZ (US)

Correspondence Address: SCHWEGMAN, LUNDBERG, WOESSNER & KLUTH, P.A., P.O. BOX 2938, MINNEAPOLIS, MN, 55402, US

(21) Appl. No.: 11/173,222

(22) Filed: Jun. 30, 2005

(51) Int. Cl. H05K 7/10; H01L 23/055

(52) U.S. Cl. 361/774; 257/698

(57) ABSTRACT

In some example embodiments, an electronic assembly includes a substrate and an electronic package. The substrate includes a hole that extends partially through the substrate. The electronic package includes a pin that extends from the electronic package. The pin is inserted into the hole that extends partially through the substrate. The substrate may be a motherboard that includes an upper surface and a lower surface with one or more conductive paths between the upper surface and the lower surface. The pin may engage at least one of the conductive paths. The pin and the hole may be any size, shape or geometry that permits the electronic package to be bonded to the motherboard. In addition, the hole may extend to any depth through the substrate as long as long the hole extends partially through the substrate and not all of the way through the substrate.

### TECHNICAL FIELD

Some example embodiments of the present invention relate to an electronic package connected to a substrate, and more particularly, to an electronic assembly where the pins of an electronic package are directly connected to a substrate.

### BACKGROUND

Electronic assemblies that include processors are continually being required to handle ever-increasing numbers of current paths in order to operate the processors. Processors typically require more current paths in order to operate at higher frequencies and to simultaneously perform numerous logic and memory operations. As processor densities continue to increase, so does the structural challenge of adhering electronic packages that include processors to a motherboard.

One example method of attaching an electronic package to a motherboard includes surface mounting the electronic package to the motherboard using a soldered connection. One drawback with soldering the electronic package to the motherboard is that the various components contract at different rates during bonding. The different rates of contraction are due to differences in the coefficients of thermal expansion for the materials that form the electronic package, solder and motherboard. Since the electronic package, solder and motherboard contract at different rates, stress forms within the electronic assembly as the solder hardens to bond the electronic package to the motherboard.

The stress that is formed within the electronic package, solder and motherboard renders such electronic assemblies vulnerable to shock and vibration forces. As an example, when a motherboard is mounted within a chassis that is shipped to an end user, the electronic assembly may be exposed to potentially harmful shock and vibration forces.

One available alternative is to use adhesives to attach an electronic package to a motherboard. However, adhesives are limited in both thermal and electrical conductivity.

Another alternative is to use electronic packages that include pins which extend from the package. The pins of the electronic package typically extend through the motherboard where they are soldered in place on an opposing side of the motherboard to the electronic package.

One of the drawbacks with connecting pins to the motherboard in this manner is that the ends of the pins protrude from the opposing side of the motherboard to the electronic package. The protruding pins add unwanted thickness to such electronic assemblies. In addition, each hole that extends through the motherboard takes up valuable space on the motherboard (or similar substrate).

### BRIEF DESCRIPTION OF THE DRAWINGS

FIG. 1 is a schematic section view of an electronic assembly that includes an electronic package attached to a substrate.

FIG. 2 is a schematic partially exploded section view of another electronic assembly that includes an electronic package attached to a substrate.

FIG. 3 is a schematic assembled section view of the electronic assembly shown in FIG. 2.

FIG. 4 illustrates a method that includes inserting a pin which extends from an electronics package into a hole in a substrate to attach the electronics package to the substrate.

FIG. 5 is a block diagram of an electronic system that incorporates an electronic assembly.

### DETAILED DESCRIPTION

The following detailed description references the accompanying drawings. Like numerals describe substantially similar components throughout each of the drawings. Other embodiments may be used, and structural, logical, and electrical changes made. The electronic assemblies described herein can be manufactured, used, or shipped in a number of positions and orientations.

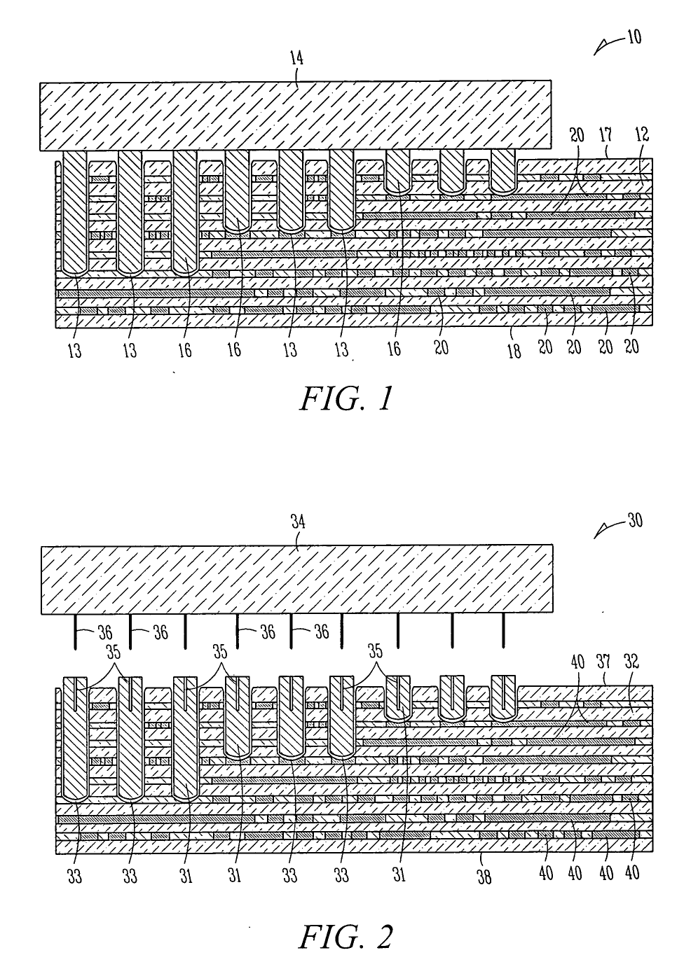

FIG. 1 illustrates an electronic assembly 10 that includes a substrate 12 and an electronic package 14. The substrate 12 defines one or more holes 13 that extend partially through the substrate 12. The electronic package 14 includes pins 16 that extend from the electronic package 14. The pins 16 are inserted into the holes 13 that extend partially through the substrate 12.

The connection between the electronic package 14 and the substrate 12 via pins 16 may make it easier to remove and/or replace the electronic package 14. As 10 examples, the electronic assembly 10 may be exposed to heat, chemicals or some type of force that facilitates removing the pins 16 of the electronic package 14 from the substrate 12.

In the example embodiment shown in FIG. 1, the substrate 12 is a motherboard that includes an upper surface 17 and a lower surface 18 with one or more conductive paths 20 between the upper surface 17 and the lower surface 18. The pins 16 may engage at least one of the conductive paths 20. It should be noted that pins 16 and the holes 13 may be any size, shape or geometry that permits electronic package 14 to be bonded to motherboard 12.

In addition, the holes 1 3 may extend to any depth through the substrate 12 as long as the holes 13 extend only partially through the substrate 12 and not all of the way through substrate 12. The amount that a particular hole 13 extends through the substrate 12 may depend in part on (i) the position of any conductive paths 20 that are between the upper surface 17 and the lower surface 18 of the substrate 12; (ii) the size of a particular pin 16 that extends from electronic package 14; and (iii) the application where the electronic assembly 10 will be used (among other factors). In some embodiments, the pins 16 may be different lengths and the holes 13 may extend different distances through the substrate 12.

The ability to connect the pins 16 to the conductive paths 20 may improve the integrity of signals that are delivered back and forth to the electronic package 14 at relatively high speeds. The signal integrity improves because the conductive paths 20 provide a more direct passageway between the electronic package 14 and other electrical components that may be connected to the substrate 12.

The electronic package 14 may include a processor (not visible in FIG. 1) that is electrically coupled to the pins 16. The type of processor that is included in the electronic package 14 will depend in part on the application where the electronic assembly 10 will be used.

The pins 16 may be attached to the substrate 12 within the holes 13 in any manner. As examples, electronic assembly 10 may include an adhesive, or a solder, that serves to connect the pins 16 to the substrate 12.

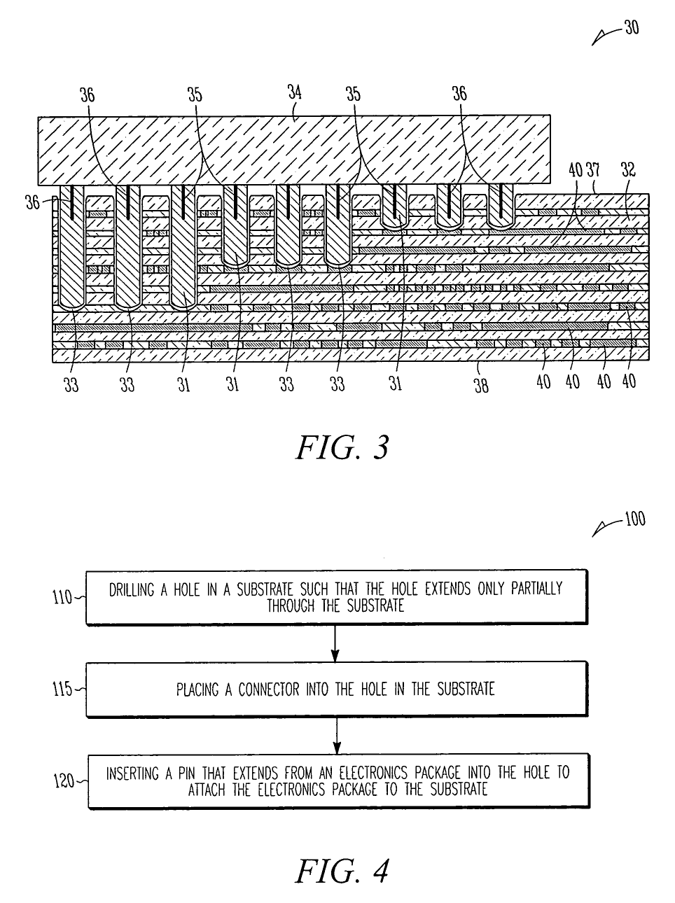

FIGS. 2 and 3 illustrate another example electronic assembly 30 that includes a substrate 32, one or more connectors 31 and an electronic package 34. The substrate 32 defines holes 33 that extend partially through the substrate 32. The connectors 31 are inserted into the holes 33 (see FIG. 2).

The electronic package 34 includes pins 36 that extend from the electronic package 34. As shown in FIG. 3, the pins 36 are inserted into openings 35 in the connectors 31 such that the pins 36 and connectors 31 electrically couple the electronic package 34 to the substrate 32.

In the example embodiment shown in FIGS. 2 and 3, the substrate 32 may be a motherboard that includes an upper surface 37 and a lower surface 38 with one or more conductive paths 40 located between the upper surface 37 and the lower surface 38. The connectors 31 may engage at least one of the conductive paths 40.

It should be noted that the connectors 31, pins 36, openings 35 and holes 33 may be any size, shape or geometry that permits electronic package 34 and the connector 31 to be bonded to substrate 32. In addition, the holes 33 may extend to any depth through the substrate 32 as long as long the holes 33 extend partially through the substrate 32 and not all of the way through substrate 32. The amount that a particular hole 33 extends through the substrate 32 may depend in part on (i) the position of any conductive paths 40 that are between the upper surface 37 and the lower surface 38 of the substrate 32; (ii) the size of a particular pin 36 that extends from electronic package 34; (iii) the size of a particular connector 31 that is positioned within the hole 33; and (iv) the application where the electronic assembly 30 will be used (among other factors). In some embodiments, at least some of the holes 33 extend different distances through the substrate than other holes 33, and at least some of the pins 36 haves different lengths than other pins 36.

The electronic package 34 may include a processor (not visible in FIGS. 2 and 3) that is electrically coupled to the pins 36. The type of processor that is included in the electronic package 34 will depend in part on the application where the electronic assembly 30 will be used.

The pins 36 may be attached to the connectors 31 in any manner. As examples, the electronic assembly 30 may include an adhesive, or a solder, that serves to connect the pins 36 to the connectors 31. In some embodiments, the pins 36 may be press fit into the connectors 31 such that no additional materials are required to attach the pins 36 to the connectors 31.

The connectors 31 may be attached to the substrate 32 within the holes 33 in any manner. As examples, the electronic assembly 30 may include an adhesive, or a solder, that serves to attach the connectors 31 to the substrate 32. It should be noted that the connectors 31 may fill a portion of the holes 33, or fill the entire holes 33. In addition, a portion of one or more connectors 31 may protrude from the holes 33. In some embodiments, the connectors 31 may be press fit into the substrate 32 such that no additional materials are required to attach the connectors 31 to the substrate 32.

The types of materials that are selected for the pin 36, connector 31 and substrate 32 depend on the application where the electronic assembly 30 is to be used. The size, type and alignment of electronic package 34 may vary depending on the design of electronic assembly 30. In addition, the components that make up electronic assembly 30 will be determined based on the space available and the application where electronic assembly 30 is to be used (among other factors).

It should be noted that any of the electronic packages described or referenced herein may include a processor of any type. As used herein, processor means any type of circuit such as, but not limited to, a microprocessor, a microcontroller, a graphics processor or a digital signal processor. The electronic packages described or referenced herein may also include custom circuits, or an application-specific integrated circuit, such as a communications circuit for use in wireless devices such as cellular telephones, pagers, portable computers, two-way radios, and similar electronic systems.

FIG. 4 illustrates an example method 100 that includes 110 drilling a hole in a substrate (e.g., a motherboard) such that the hole extends partially through the substrate. The method further includes 120 inserting a pin that extends from an electronics package into the hole to attach the electronics package to the substrate.

It should be noted that the hole (or holes) may be partially drilled through the substrate in any manner that is known now (e.g., laser drilling) or discovered in the future. In addition, the pin may be attached to the substrate in any manner that is known now or discovered in the future (e.g., by using an adhesive or solder).

In some embodiments, the method 100 may further include 115 placing a connector into the hole in the substrate such that 120 inserting a pin that extends from an electronics package may include inserting the pin into the connector. As an example, 130 placing the connector into the hole in the substrate may include pressing the connector into the substrate. It should be noted that the connector may be attached to the substrate in any manner that is known now (e.g., by using an adhesive or solder) or discovered in the future. In addition, 120 inserting the pin into the connector may include pressing the pin into the connector.

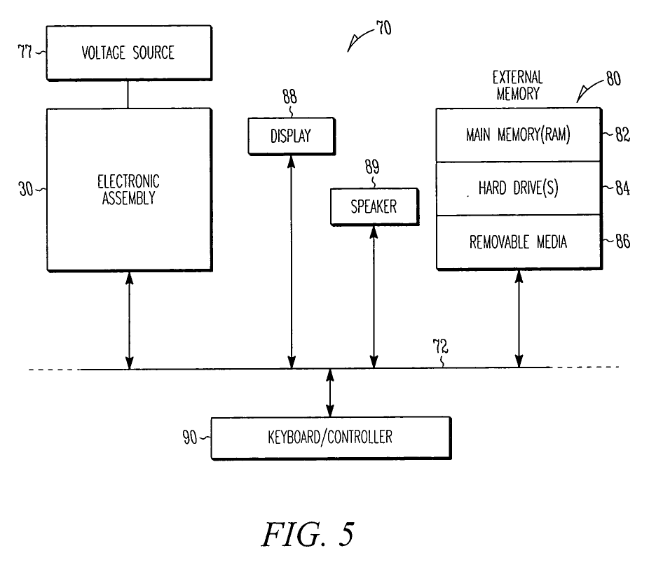

FIG. 5 is a block diagram of an electronic system 70 that incorporates at least one electronic assembly described herein (e.g., electronic assembly 10 shown in FIG. 1 or electronic assembly 30 shown in FIGS. 2 and 3). Electronic system 70 may be a computer system that includes a system bus 72 which electrically couples the various components of electronic system 70 together. System bus 72 may be a single bus or any combination of busses.

An electronic assembly as described herein (e.g., electronic assembly 30) is electrically coupled to system bus 72, and as discussed above, may include any circuit, or combination of circuits. Electronic system 70 may also include an external memory 80 that in turn may include one or more memory elements suitable to a particular application. Some example memory elements include a main memory 82 in the form of random access memory (RAM), one or more hard drives 84, or one or more drives that handle removable media 86, such as diskettes, compact disks (CDs) and digital video disks (DVDs). The electronic system 70 may also include a display device 88, a speaker 89, and a controller 90, such as a keyboard, mouse, trackball, game controller, microphone, voice-recognition device, or any other device that inputs information into the electronic system 70.

In some embodiments, electronic system 70 may further include a voltage source 77 that is electrically coupled to electronic assembly 30. Voltage source 77 may be used to supply power to a die (e.g., a processor) that is within electronic assembly 30.

The methods and electronic assemblies described herein may be implemented in a number of different embodiments, including an electronic package, an electronic system, a computer system, and one or more methods of fabricating an electronic assembly. The elements, materials, geometries, dimensions, and sequence of operations can all be varied to suit particular packaging requirements.

FIGS. 1-5 are merely representational and are not drawn to scale. Certain proportions thereof may be exaggerated while others may be minimized.

The electronic assembly described above may provide a solution for bonding an electronic package to a motherboard. Many other embodiments will be apparent to those of skill in the art after reviewing the above detailed description.

What is claimed:

1. An electronic assembly comprising:
a substrate that defines a hole which extends only partially through the substrate; and
an electronic package that includes a pin extending from the electronic package, the pin being inserted into the hole.

2. The electronic assembly of claim 1 wherein the substrate is a motherboard.

3. The electronic assembly of claim 1 further comprising solder that connects the pin to the substrate.

4. The electronic assembly of claim 1 wherein the electronic package includes a processor that is electrically coupled to the pin.

5. The electronic assembly of claim 1 wherein the substrate includes an upper surface and a lower surface with a conductive path between the upper surface and the lower surface, the pin engaging the conductive path.

6. The electronic assembly of claim 1 wherein the substrate includes a plurality of holes which extend only partially through the substrate, and the electronic package includes a plurality of pins that extend from the electronic package, at least some of the holes extending different distances through the substrate than other holes, and at least some of the pins having different lengths than other pins.

7. An electronic assembly comprising:
a substrate that defines a hole which extends only partially through the substrate;
a connector inserted into the hole; and
an electronic package that includes a pin extending from the electronic package, the pin being inserted into the connector.

8. The electronic assembly of claim 7 wherein the substrate is a motherboard.

9. The electronic assembly of claim 7 wherein the connector is pressed into the hole.

10. The electronic assembly of claim 7 wherein the pin is pressed into the connector.

11. The electronic assembly of claim 7 wherein the substrate includes an upper surface and a lower surface with a conductive pathway between the upper surface and the lower surface, the connector engaging the conductive pathway.

12. The electronic assembly of claim 7 wherein the substrate includes a plurality of holes which extend only partially through the substrate, and the electronic package includes a plurality of pins that extend from the electronic package, at least some of the holes extending different distances through the substrate than other holes, and at least some of the pins having different lengths than other pins.

13. A method comprising:
drilling a hole in a substrate such that the hole extends only partially through the substrate; and
inserting a pin that extends from an electronics package into the hole to attach the electronics package to the substrate.

14. The method of claim 13 further comprising placing a connector into the hole in the substrate, and wherein inserting a pin that extends from an electronics package includes inserting the pin into the connector.

15. The method of claim 14 wherein placing the connector into the hole in the substrate includes pressing the connector into the substrate.

16. The method of claim 14 wherein inserting the pin into the connector includes pressing the pin into the connector.

17. The method of claim 13 wherein drilling a hole in a substrate includes drilling a hole in a motherboard.

18. An electronic system comprising:
a bus;
a random access memory coupled to the bus; and
an electronic assembly coupled to the bus, the electronic assembly including a substrate and an electronic package, the electronic package including a pin that extends from the electronic package such that the pin is positioned within a hole that extends only partially through the substrate.

19. The electronic system of claim 18 further comprising a voltage source electrically coupled to the electronic package.

20. The electronic system of claim 19 wherein the electronic package includes a processor and the voltage source supplies power to the processor.

21. The electronic system of claim 18 wherein the electronic assembly further includes a connector inserted into the hole in the substrate such that the pin which extends from the electronic package is inserted into the connector.

22. The electronic system of claim 21 wherein the connector is pressed into the hole and the pin is pressed into the connector.

23. The electronic system of claim 18 wherein the substrate is a motherboard.
